(19) United States
(12) Patent Application Publication
(10) Pub. No.: US 2010/0060491 A1
(43) Pub. Date: Mar. 11, 2010

(54) Operating apparatus and electronic device having the same

(75) Inventors: Doo Yoo Kim, Cheongiu-si (KR); Jae Sung Park, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si, (KR)

(21) Appl. No.: 12/453,482

(22) Filed: May 12, 2009

(30) Foreign Application Priority Data
Sep. 8, 2008 (KR) 2008-88020

(51) Int. Cl. H03M 11/14

(52) U.S. Cl. 341/23; 341/22

(57) ABSTRACT

Disclosed herein are an operating apparatus and an electronic device having the same. According to the operating apparatus, key values of a button can be variably changed each time a key value changing button is pushed so that the button can have several key values. Accordingly, a variety of functions of the electronic device can be achieved although the total number of the buttons is reduced.

### CROSS-REFERENCE TO RELATED APPLICATIONS

This application claims the priority benefit of Korean Patent Application No. 2008-0088020, filed on Sep. 8, 2008 in the Korean Intellectual Property Office, the disclosure of which is incorporated herein by reference.

### BACKGROUND

1. Field

Embodiments relate to an operating apparatus and an electronic device having the same, and more particularly, to an operating apparatus to input a predetermined operational signal to an electronic device, and the electronic device having the same.

2. Description of the Related Art

Electronic devices, for example an air conditioner, are equipped with an operating apparatus enabling a user to input predetermined operational signals.

In general, the operating apparatus is configured in a manner that buttons and key pads are sequentially deposited and connected on a substrate. As the buttons are pushed by a user, signals are selectively exchanged between the buttons and terminals formed at the key pads. The operational signals are thus input through the signal exchange between the buttons and the key pad terminals, and accordingly the substrate perceives the signals and controls the device.

The button includes a printed side printed with figures, diagrams or letters, so that the user can check the printed patterns and select desired buttons. Optionally, the button may be equipped with a light source including a light emitting diode (LED) disposed under the button so that the printed side can be recognized even in a dark state, for example, at night. As the LED emits light, the user can recognize the figures, diagrams or letters on the printed side by a backlighting effect.

In case of an air conditioner, the operating apparatus is mounted at one side on a front panel of the air conditioner, including diverse buttons to be input with various functions regarding a wind direction, a wind force, temperature and the like by the user.

Recently, although it is required to increase the number of the buttons as functions of the electronic devices are diversified, a button mounting space is being decreased, which restricts the increase of the number of buttons.

### SUMMARY

Therefore, it is an aspect of exemplary embodiments to provide an operating apparatus for an electronic device, capable of implementing various functions of the device while reducing the number of operation buttons, by allocating a plurality of functions to one operation button, and the electronic device having the same.

Additional aspects of exemplary embodiments will be set forth in part in the description which follows and, in part, will be obvious from the description, or may be learned by practice of exemplary embodiments.

In accordance with one aspect of exemplary embodiments, there is provided an operating apparatus including a first button that changes key values, and a second button which changes the key values according to operation of the first button.

The key values of the second button may be alternately changed each time the first button is operated.

The second button may include two buttons having key values opposite to each other.

The second button may include patterns denoting the key values, and the patterns are alternately changed each time the first button is operated.

The patterns may include any one of figures, diagrams, and letters, or combination of figures, diagrams, and letters.

The second button may include a casing, a plurality of light sources mounted in the casing, a plurality of first polarizing sheets disposed corresponding to the light sources to transmit lights in respectively different directions according to the light sources, and a plurality of second polarizing sheets each including a transmission part to transmit the lights of all directions transmitted through the first polarizing sheets, and a pattern part to block lights being incident in directions other than a predetermined direction.

The light sources may each include a light emitting diode (LED) emitting lights of the same wavelength.

The pattern part may be shaped in any of signs, figures, diagrams and letters.

The transmission part may be shaped in any of signs, figures, diagrams and letters.

The plurality of second polarizing sheets may selectively include a first polarizing sheet having the signs, a second polarizing sheet having the figures, a third polarizing sheet having the diagrams, and a fourth polarizing sheet having the letters.

In accordance with another aspect of exemplary embodiments, there is provided an electronic device an electronic device including an operating apparatus which includes a first button that changes key values, and a second button which changes the key values according to operation of the first button, and a control unit which changes the key values of the second button when the first button is pushed.

The control unit may alternately change the key values of the second button each time the first button is operated.

The second button may include a casing, a plurality of light sources mounted in the casing, a plurality of first polarizing sheets disposed corresponding to the light sources to transmit lights in respectively different directions according to the light sources, and a plurality of second polarizing sheets each including a transmission part to transmit the lights of all directions transmitted through the first polarizing sheets, and a pattern part to block lights being incident in directions other than a predetermined direction.

The control unit may turn on the plurality of light sources sequentially each time the first button is operated.

In accordance with another aspect of the present invention exemplary embodiments, there is provided a control apparatus for controlling an electronic device, the control apparatus including a first button operated by a user to alternately change key values of at least one second button; and a control unit which alternately changes key values of at least one second button in response to operation of the first button by the user, wherein the control unit instructs the electronic device to operate in response to operation of at least one second button.

The operation of the first button may performed when the user pushes the first button.

The operation of the at least one second button may performed when the user pushes the at least one second button.

The at least one second button may include a casing; a plurality of light sources mounted in the casing; a plurality of first polarizing sheets disposed corresponding to the light sources to transmit lights in respectively different directions according to the light sources; and a plurality of second polarizing sheets each including a transmission part to transmit the lights of all directions transmitted through the first polarizing sheets, and a pattern part to block lights being incident in directions other than a predetermined direction.

In an operating apparatus and electronic device according to an exemplary embodiment, key values of the button can be variably changed each time the key value changing button is pushed so that the button can have several key values. Accordingly, a variety of functions or operations of the electronic device can be achieved while reducing the total number of the buttons.

### BRIEF DESCRIPTION OF THE DRAWINGS

These and/or other aspects of exemplary embodiments will become apparent and more readily appreciated from the following description of exemplary embodiments, taken in conjunction with the accompanying drawings of which:

FIG. 1 is a perspective view of an air conditioner equipped with an operating apparatus according to an exemplary embodiment;

FIG. 2 is a perspective view schematically showing a second button shown in FIG. 1;

FIG. 3 is a sectional view of the second button shown in FIG. 2;

FIG. 4 shows a pattern of the second button shown in FIG. 3, in a state where light is emitted from a first light source but not from a second light source;

FIG. 5 shows a pattern of the second button shown in FIG. 3, in a state where light is emitted from the second light source but not from the first light source;

FIG. 6 is a control block diagram of the air conditioner equipped with the operating apparatus according to an exemplary embodiment; and

FIGS. 7-9 show that functions of the second button are changed as the first button is pushed, in an operating apparatus according to another exemplary embodiment.

### DETAILED DESCRIPTION

Reference will now be made in detail to exemplary embodiments, examples of which are illustrated in the accompanying drawings, wherein like reference numerals refer to the like elements throughout. Exemplary embodiments are described below to explain exemplary embodiments by referring to the figures.

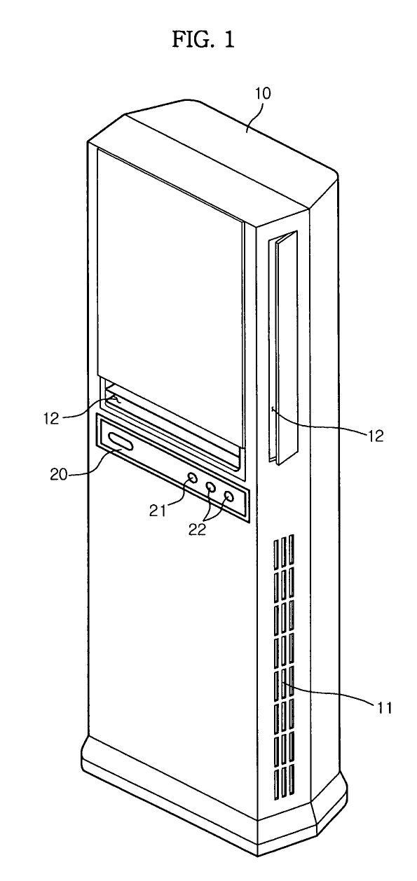

FIG. 1 shows an air conditioner equipped with an operating apparatus 20 according to an exemplary embodiment. Referring to FIG. 1, the air conditioner includes a main body 10 in a box form. The main body 10 includes side suction inlets 11 on both lower sides thereof to draw in the interior air. Exhaustion outlets 12 are formed at the front and both upper sides of the main body 10 to exhaust a conditioned air being driven by a ventilation unit mounted therein, to the interior space. Inside the main body 10, additionally, are mounted a heat exchange unit (not shown) to perform heat exchange and the ventilation unit to drive the conditioned air to the interior space.

With the above structure, the air conditioner cools or heats the interior air through processes of drawing in the interior air through the side suction inlets 11, performing heat exchange, and exhausting the conditioned air to the interior space through the exhaustion outlets 12.

The operating apparatus 20 is disposed below the front exhaustion outlet 12. The operating apparatus 20 includes a first button 21 for change of key values and a second button 22 changed in its key values according to the operation of the first button 21. A user can select a desired function through the first button 21 and then command the air conditioner to perform the function through the second button 22. Although the two types of buttons 21 and 22 are illustrated in this exemplary embodiment, exemplary embodiments are not limited to the number of the buttons and so may include one or more than one button. In addition, exemplary embodiments are not limited to one first button. Exemplary embodiments may include more than one first button. Further, exemplary embodiments are not limited to one second button. Exemplary embodiments may include more than one second button.

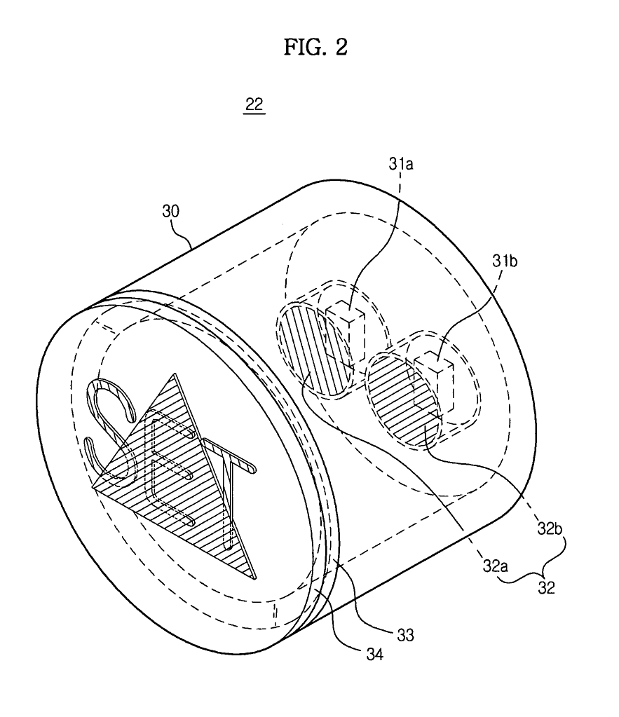

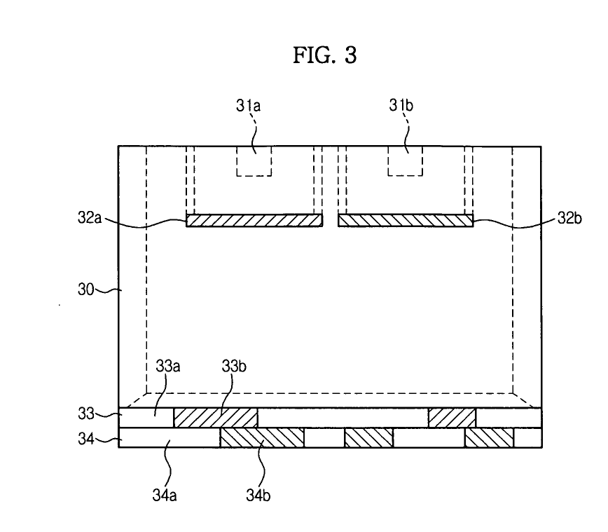

FIG. 2 schematically shows the second button 22 formed at the operating apparatus according to an exemplary embodiment. FIG. 3 is a sectional view of the second button 22.

Referring to FIG. 2 and FIG. 3, the second button 22 includes a cylindrical casing 30, a plurality of, for example, two light sources 31a and 31b mounted in the casing 30, and polarizing members 32, 33 and 34 transmitting light having a predetermined incident angle while blocking light of the other incident angles, among lights emitted from the light sources 31a and 31b.

The polarizing members 32, 33 and 34 may include a plurality of polarizing sheets 32, 33 and 34. The first polarizing sheets 32 are disposed corresponding to the light sources 31a and 31b to polarize the lights respectively in different directions according to the light sources 31a and 31b. The second polarizing sheet 33 and the third polarizing sheet 34 are disposed at a predetermined distance from the respective first polarizing sheets 32, both having greater diameters than the first polarizing sheet 32.

The second and the third polarizing sheets 33 and 34 respectively include transmission parts 33a and 34a transmitting all the lights passed through the first polarizing sheets 32, and pattern parts 33b and 34b blocking lights being incident in directions other than a predetermined direction.

The second and the third polarizing sheets 33 and 34 each include a polarizing pattern area having predetermined patterns. The polarizing pattern areas of the second and the third polarizing sheets 33 and 34 block transmission of the lights incident in certain directions, thereby displaying the shape of the predetermined polarizing patterns. Hereinafter, technical features of exemplary embodiments will be described with reference to the illustrated structures of the second button 22 and the respective polarizing sheets 32 to 34, and light advancing paths being different according to the sheets 32 to 34.

The light source 31 includes the first light source 31a and the second light source 31b regardless of colors. Generally known light emitting diodes (LED) or other light emitting devices can be employed as the light sources 31a and 31b.

The first polarizing sheets 32 are disposed corresponding to the first and the second light sources 31a and 31b and polarize lights emitted from the respective light sources 31a and 31b, in predetermined directions. For example, if a polarizing sheet 32a corresponding to the first light source 31a is a 90° polarizing film, a 180° polarizing film may be applied to a polarizing sheet 32b corresponding to the second light source 31b.

The second and the third polarizing sheets 33 and 34 respectively include the transmission parts 33a and 34a, and the pattern parts 33b and 34b. More specifically, the second and the third polarizing sheets 33 and 34 have the pattern parts 33b and 34b each having a predetermined pattern such as a triangle and letters “set” shown in FIG. 2. The patterns parts 33b and 34b block transmission of lights being incident in directions other than the predetermined direction. On the contrary, the pattern parts 33b and 34b may be applied to the background areas of the polarizing sheets 33 and 34 excluding the pattern areas in the form of figures, diagrams or letters.

The second polarizing sheet 33 includes the pattern part 33b blocking the lights incident not in the same direction as the polarizing sheet 32a.

The third polarizing sheet 34 includes the pattern part 34b blocking the lights being incident not in the same direction as the polarizing sheet 32b.

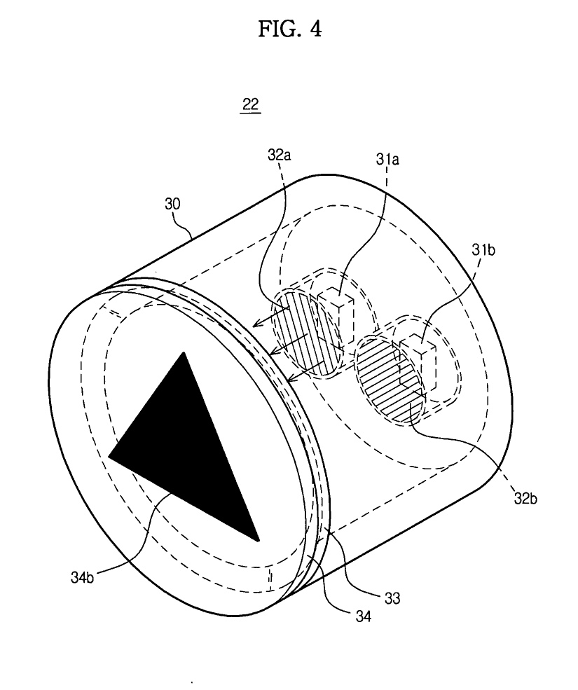

As shown in FIG. 4, when the first light source 31a is turned on, the light emitted from the first light source 31a is polarized in a certain direction and transmitted through the first polarizing sheet 32a. The light passed through the first polarizing sheet 32a can transmit both the transmission part 33a and the pattern part 33b of the second polarizing sheet 33 but, at the third polarizing sheet 34, can transmit only the transmission part 34a while blocked by the pattern area 34b. Accordingly, the area where the light is blocked by the pattern parts 34b of the third polarizing sheet 34 is shown as a dark pattern to the user. That is, in the case shown in FIG. 2, the user is able to recognize the triangle pattern generated as the pattern part 34b blocks the light.

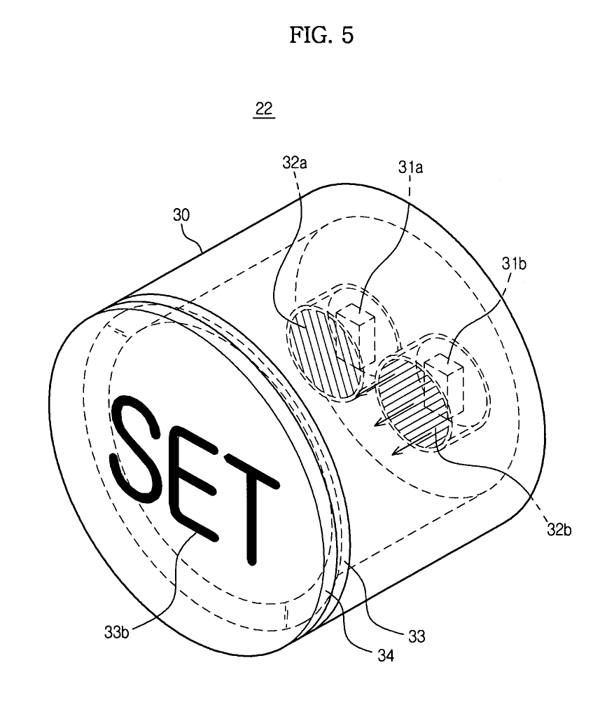

Referring to FIG. 5, when the second light source 31b is turned on, the light emitted from the second light source 31b is polarized in a certain direction and transmitted through the first polarizing sheet 32b. The light passed through the first polarizing sheet 32b is transmitted through only the transmission part 33a but blocked by the pattern part 33b of the second polarizing sheet 33. Also, after passing through the transmission part 33a of the second polarizing sheet 33, the light transmits both the transmission part 34a and the pattern part 34b of the third polarizing sheet 34. Accordingly, the area where the light is blocked by the pattern part 33b of the second polarizing sheet 33 is shown as a dark pattern to the user so that the user is able to recognize the letter pattern “set” in the case shown in FIG. 2.

As shown in FIG. 4 and FIG. 5, as described above, when the first light source 31a is turned on, the second button 22 can be used as a function button displaying the triangle pattern and, when the second light source 31b is turned on, as a function button displaying the letter pattern “set.” In addition, the patterns displayed on the second button 22 may denote opposite functions to each other, for example, figures of a triangle and an inverse triangle or letters of “set” and “cancel.”

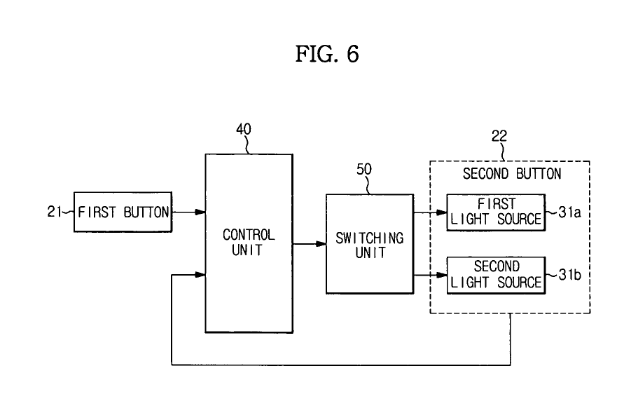

As shown in FIG. 6, an electronic device equipped with the operating apparatus according to an exemplary embodiment includes a control unit 40 controlling the overall operation of the device and a switching unit 50.

The first and the second buttons 21 and 22 of the operating apparatus 20 are operated by the user's pushing or touching. When the user pushes the first button 21 of the operating apparatus 20, the control unit 40 turns on and off the first light source 31a or the second light source 31b, selectively, formed on the second button 21 through the switching part 50. Specifically, the second unit 40 may sequentially turn on the first and the second light sources 31a and 31b each time of pushing the first button 21. Here, the control unit 40 may turn on a light source which is preset to operate in response to the number of pushings of the first button 21.

When the first button 21 is pushed, the control unit 40 operates to change a key value of the second button 22. Here, the control unit 40 understands the key values of the second button 22 differently according to states of the first and the second light source 31a and 31b. For example, if the second button 22 is pushed with the first light source 31a being in an on state, the control unit 40 recognizes the key value related to increase of the temperature. If the second button 22 is pushed when the first light source 31b is in an on state, the control unit 40 recognizes the key value related to increase of a wind force.

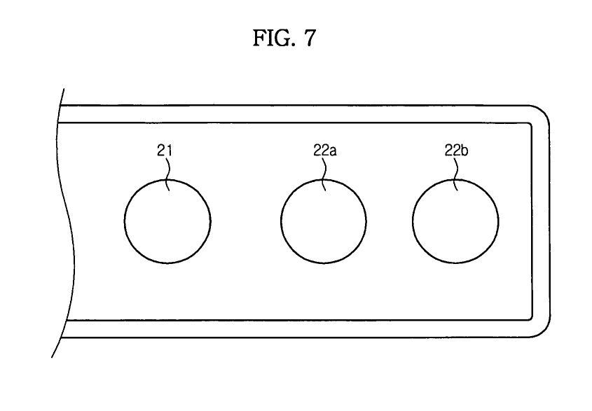

FIG. 7 to FIG. 9 show that functions of the second button are changed as the first button is pushed, in an operating apparatus according to another exemplary embodiment.

As shown in FIG. 7, the operating apparatus 20 includes one first button 21 (first type of button) and two second buttons 22a and 22b (second type of button). When the first button 21 is not pushed by the user yet, the second buttons 22a and 22b display initial states. In this state, light sources of the second buttons 22a and 22b are in an off state.

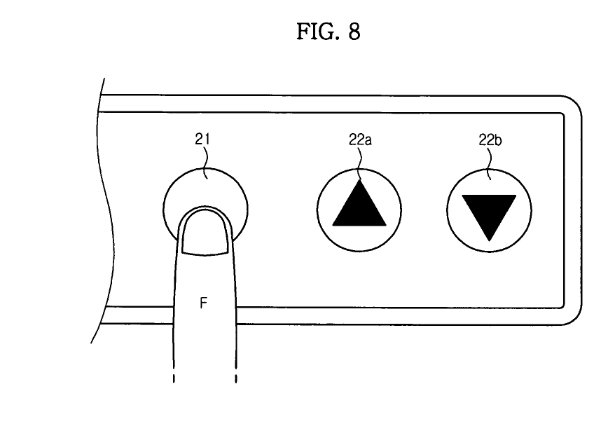

Referring to FIG. 8, when the user's finger F pushes the first button 21, any of the two light sources corresponding to the two second buttons 22a and 22b is turned on. According to this, predetermined patterns formed on the second buttons 22a and 22b are displayed through polarizing sheets. In this exemplary embodiment, the second buttons 22a and 22b have key values opposite to each other and patterns corresponding to the respective key values. As shown in FIG. 8, for example, the second button 22a may have a triangle pattern to denote increase of a certain set value while the second button 22b has an inverse triangle pattern to denote decrease of the certain set value.

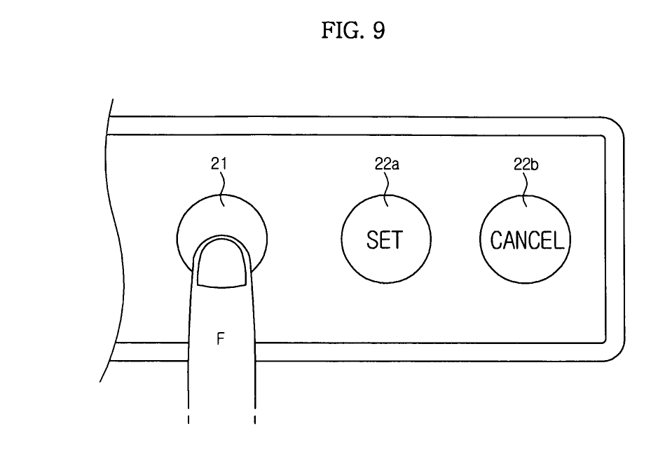

Referring to FIG. 9, when the user's finger F pushes the first button 21 once more, the one of the light sources that has been in the on state is now turned off whereas the other light source that has been in the off state is turned on. Accordingly, there are displayed other patterns different from the previous patterns shown through the polarizing sheets. As shown in FIG. 9, while the second button 22a shows the letter pattern “set” to denote setting of the function, the second button 22b shows the letter pattern “cancel” to denote cancellation of the set function.

Although a few exemplary embodiments have been shown and described, it would be appreciated by those skilled in the art that changes may be made in these exemplary embodiments without departing from the principles and spirit of the disclosure, the scope of which is defined in the claims and their equivalents.

What is claimed is:

1. An operating apparatus comprising:
a first button that changes key values; and
a second button which changes the key values according to operation of the first button.

2. The operating apparatus according to claim 1, wherein the key values of the second button are alternately changed each time the first button is operated.

3. The operating apparatus according to claim 1, wherein the second button comprises two buttons having key values opposite to each other.

4. The operating apparatus according to claim 1, wherein the second button includes patterns denoting the key values, and the patterns are alternately changed each time the first button is operated.

5. The operating apparatus according to claim 4, wherein the patterns comprise any one of figures, diagrams and letters, or any combination of figures, diagrams, and letters.

6. The operating apparatus according to claim 1, wherein the second button comprises:
a casing;
a plurality of light sources mounted in the casing;
a plurality of first polarizing sheets disposed corresponding to the light sources to transmit lights in respectively different directions according to the light sources; and
a plurality of second polarizing sheets each including a transmission part to transmit the lights of all directions transmitted through the first polarizing sheets, and a pattern part to block lights being incident in directions other than a predetermined direction.

7. The operating apparatus according to claim 6, wherein the light sources each comprise a light emitting diode (LED) emitting lights of the same wavelength.

8. The operating apparatus according to claim 7, wherein the pattern part is shaped in any of signs, figures, diagrams and letters.

9. The operating apparatus according to claim 7, wherein the transmission part is shaped in any of signs, figures, diagrams and letters.

10. The operating apparatus according to claim 8, wherein the plurality of second polarizing sheets selectively comprise:
a first polarizing sheet having the signs;
a second polarizing sheet having the figures;
a third polarizing sheet having the diagrams; and
a fourth polarizing sheet having the letters.

11. An electronic device comprising:
an operating apparatus which includes a first button that changes key values, and a second button which changes the key values according to operation of the first button; and
a control unit which changes the key values of the second button when the first button is pushed.

12. The electronic device according to claim 11, wherein the control unit alternately changes the key values of the second button each time the first button is operated.

13. The electronic device according to claim 11, wherein the second button comprises:
a casing;
a plurality of light sources mounted in the casing;
a plurality of first polarizing sheets disposed corresponding to the light sources to transmit lights in respectively different directions according to the light sources; and
a plurality of second polarizing sheets each including a transmission part to transmit the lights of all directions transmitted through the first polarizing sheets, and a pattern part to block lights being incident in directions other than a predetermined direction.

14. The electronic device according to claim 13, wherein the control unit turns on the plurality of light sources sequentially each time the first button is operated.

15. The operating apparatus according to claim 2, wherein the second button comprises two buttons having key values opposite to each other.

16. A control apparatus for controlling an electronic device, the control apparatus comprising:
a first button operated by a user to alternately change key values of at least one second button; and
a control unit which alternately changes key values of at least one second button in response to operation of the first button by the user,
wherein the control unit instructs the electronic device to operate in response to operation of at least one second button.

17. The control apparatus of claim 16, wherein operation of the first button is performed when the user pushes the first button.

18. The control apparatus of claim 16, wherein operation of the at least one second button is performed when the user pushes the at least one second button.

19. The control apparatus according to claim 16, wherein the at least one second button comprises:
a casing;
a plurality of light sources mounted in the casing;
a plurality of first polarizing sheets disposed corresponding to the light sources to transmit lights in respectively different directions according to the light sources; and
a plurality of second polarizing sheets each including a transmission part to transmit the lights of all directions transmitted through the first polarizing sheets, and a pattern part to block lights being incident in directions other than a predetermined direction.
